(19) United States
(12) Patent Application Publication
(10) Pub. No.: US 2006/0022325 A1
(43) Pub. Date: Feb. 2, 2006

(54) Cap wafer, semiconductor package, and fabricating method thereof

(75) Inventors: Jun-sik Hwang, Yongin-si (KR); Woon-bae Kim, Suwon-si (KR); Chang-youl Moon, Suwon-si (KR); In-sang Song, Seoul (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/189,725

(22) Filed: Jul. 27, 2005

(30) Foreign Application Priority Data
Jul. 27, 2004 (KR) 2004-58719

(51) Int. Cl. H01L 23/544

(52) U.S. Cl. 257/690

(57) ABSTRACT

A cap wafer including a cavity, a packaged semiconductor including the cap wafer, and a method of fabricating the cap wafer. The cap wafer includes a cavity formed in an area of a lower surface of the cap wafer; and at least one feed-through penetrating through upper and lower surfaces of the cap wafer so as to be connected to the cavity. The packaged semiconductor includes a base wafer including an upper surface including an area in which a circuit device is formed; a cap wafer including a lower surface including an area in which a cavity having a predetermined size is formed, the cap wafer being combined with the base wafer to position the circuit device in the cavity so as to package the circuit device; and at least one feed-through penetrating through upper and lower portions of the cap wafer so as to be connected to the cavity and electrically connected to the circuit device.

### CROSS-REFERENCE TO RELATED APPLICATIONS

This application claims the benefit of Korean Patent Application No. 2004-58719, filed on Jul. 27, 2004, in the Korean Intellectual Property Office, the disclosure of which is incorporated herein by reference.

### BACKGROUND OF THE INVENTION

1. Field of the Invention

The present invention relates to a cap wafer for packaging a semiconductor device fabricated on a wafer, a semiconductor package including the cap wafer, and a method of fabricating the cap wafer. More particularly, the present invention relates to a cap wafer including a cavity for securing a space occupied by a semiconductor device and an electrode formed in the cavity for electrically connecting the circuit device to an external power source, a packaged semiconductor device including the cap wafer, and a method of fabricating the cap wafer.

2. Description of the Related Art

Device chips for use in various electronic products are supplied with power from an external source so as to operate the same. Such device chips include minute electronic circuits which may be easily damaged by an external impact. Thus, a process of fabricating such a device chip necessarily includes a packaging process of electrically connecting to the device chip and packaging the device chip so that the device chip can endure an external impact, and further, so as to impart physical function and shape. In particular, wafer level packaging is necessary to achieve recent trends in subminiaturization and high-performance requirements of electronic products.

In general, a cap wafer having a predetermined shape is bonded to a wafer on which a circuit device is fabricated to provide wafer level packaging.

FIG. 1 is a vertical cross-sectional view of a cap wafer disclosed in U.S. Pat. No. 6,376,280. Referring to FIG. 1, a viahole 11 is formed in a cap wafer 10 so as to penetrate through upper and lower surfaces of the cap wafer 10. Also, a predetermined type of circuit device 30 is formed on an upper surface of a base wafer 20, and a pad 22 is bonded to a bonding pad 21 electrically connected to the circuit device 30 and the cap wafer 10 so as to seal the circuit device 30. For packaging, a first gasket 13 to be bonded to the pad 22 and a second gasket 14 to be bonded to the bonding pad 21 are formed on the cap wafer 10

Wire bonding is performed through the viahole 11 to connect the circuit device 30 to an external power source. In other words, the circuit device 30 is electrically connected to the external power source via wires 12 and the bonding pad 21. However, in the case of a wire bonding method, the chip performance is deteriorated by parasitic wiring capacitance. Also, recently developed high-performance device chips require a large number of leads (paths transmitting an electric signal). However, in the wire bonding method, there is a limit to increasing the number of leads. Thus, it is difficult to apply the wire bonding method to such a high-performance device chip.

In addition, in the case where packaging is performed using the cap wafer 10 shown in FIG. 1, the bonding pad 21 electrically connected to the circuit device 30 must be formed around the circuit device 30. Thus, the size of the packaged chip is increased by the size of the bonding pad 21.

FIG. 2 is a vertical cross-sectional view of a cap wafer 40 according to another related art. The cap wafer 40 is connected to an external power source via a feed-through 41 without wire bonding. The feed-through 41 is formed by filling a viahole using a plating method.

A first sealing layer 43 is disposed at an edge of a lower surface of the cap wafer 40 for bonding to a base wafer 50. A second sealing layer 52 is disposed at an edge of an upper surface of the base wafer 50 for bonding to the cap wafer 40. Thus, when temperature and pressure are applied to the sealing layers 43 and 52, the first and the second sealing layers 43 and 52 react with each other to form a package. As a result, when the cap wafer 40 is combined with the base wafer 50, the feed-through 41 is electrically connected to a circuit device 60 on the base wafer 50 via a pad 42 and a conductive layer 51. The conductive layer 51 connects pad 42 to lead wires of the circuit device 60 on the base wafer 50. Thus, a drive signal may be transmitted from an external power source to the circuit device 60.

Since the cap wafer 40 shown in FIG. 2 uses the feed-through 41, the problem of accommodating a large number of circuit device leads may be solved. However, the cap wafer 40 requires the conductive layer 51. Thus, the size of the circuit device 60 is increased.

Also, there is a yield loss in the process of bonding the cap wafer 40 to the base wafer 50. In other words, since the conductive material for forming the feed-through 41 is different from the material for forming the cap wafer 40, the respective characteristics of the feed-through 41 and the cap wafer 40 such as thermal expansion coefficient or the like are different. Thus, when high temperature and pressure are applied during bonding, the material for the feed-through 41 expands to a lower portion. As a result, a gap between the cap wafer 40 and the base wafer 50 may be increased. If the gap between the cap wafer 40 and the base wafer 50 is increased, bonding between the sealing layers 43 and 52 may be compromised. In addition, the bonding surface 4 between the feed-through 41 formed in the viahole and the cap wafer 40 may be deformed due to application of high temperature and pressure. This problem causes some yield loss.

In fabricating the feed-through 41, the viahole is formed in the cap wafer 40. Next, a seed layer is disposed on a side surface of the viahole and an upper surface of the cap wafer 40 and plated with a plating solution.

In the case where plating is performed using such a method, the plating speed varies at each portion of the seed layer (a portion of the seed layer on the cap wafer 40 and a portion of the seed layer in the viahole). Thus, plating by means of the seed layer may fail to completely fill the viahole. As a result, cracks or voids may be formed in the viahole. If voids are formed, impurities in the voids are subject to oxidation or reaction. Thus, the device chip may break down or may be heated and damaged by current applied from an external source. If such cracks are generated, minute dust may flow into the device chip. As a result, the device chip may malfunction.

### SUMMARY OF THEE INVENTION

Accordingly, the present invention has been made to solve the abovementioned problems of the prior art, and an object of the present invention is to provide a cap wafer including a cavity and an electrode formed in the cavity so as to improve packaging yield and reduce device size as a whole and a method for fabricating the cap wafer.

The above objects of the present invention have been achieved by providing a cap wafer adapted for packaging a semiconductor device in combination with a base wafer, said cap wafer including a cavity and a feed-through formed in the cavity.

Another aspect of the invention is to provide a cap wafer including an insulating layer in a viahole so as to prevent an electric signal having a direct current (DC) component from leaking between the cap wafer and a feed-through, and a method for fabricating the same.

Another aspect of the invention is to provide a method of fabricating a feed-through by plating a viahole without disposing a seed layer on a side surface of the viahole so as to prevent the generation of cracks or voids.

The above objects of the present invention have also been achieved by providing a package including a cap wafer combined with a base wafer adapted for packaging a semiconductor device, the package including: a cavity formed in a predetermined area of a lower surface of the cap wafer; and at least one feed-through penetrating through upper and lower surfaces of the cap wafer so as to be connected to the cavity.

The cap wafer may include an insulating layer formed between the feedthrough and the cap wafer so as to insulate the feed-through from the cap wafer.

The cap wafer may include a pad formed on the lower surface of the cap wafer so as to be connected to the feed-through.

The cap wafer may include a sealing layer disposed on an area of the lower surface of the cap wafer except the cavity.

The sealing layer may comprise one or more of Au, Sn, In, Pb, Ag, Bi, Zn and Cu.

The above objects of the present invention have also been achieved by providing a packaged semiconductor comprising: a base wafer including an upper surface having a predetermined area in which a circuit device is formed; a cap wafer having a cavity formed in a predetermined area of a lower surface of the cap wafer, the cap wafer being combined with the base wafer so as to position the circuit device in the cavity and to package the same; and at least one feed-through penetrating through upper and lower portions of the cap wafer, connecting to the cavity and electrically connecting to the circuit device.

The packaged semiconductor may include an insulating layer formed between the feed-through and the cap wafer so as to insulate the feed-through from the cap wafer.

The packaged semiconductor may include a pad which electrically connects the feed-through to the circuit device.

The packaged semiconductor may further include: a first sealing layer disposed on an area of the lower surface of the cap wafer except the cavity; and a second sealing layer disposed on a portion of the upper surface of the base wafer corresponding to the first sealing layer and reacting with the first sealing layer to bond the cap wafer to the base wafer.

At least one of the first and second sealing layers may comprise one or more of Au, Sn, In, Pb, Ag, Bi, Zn, and Cu.

The above objects of the present invention have also been achieved by providing a package including a cap wafer combined with a base wafer adapted for packaging a semiconductor device, the package comprising: a cavity formed in a predetermined area of a lower surface of the cap wafer; at least one viahole positioned in the cavity and penetrating through upper and lower surfaces of the cap wafer; and a metal layer disposed on a side surface of the viahole.

The cap wafer may include an insulating layer formed between the metal layer and the cap wafer so as to insulate the metal layer from the cap wafer.

The cap wafer may include a pad formed in the cavity on the lower surface of the cap wafer for connecting to the metal layer.

The cap wafer may include a sealing layer disposed on a predetermined area of the lower surface of the cap wafer except the cavity.

The sealing layer may comprise one or more of Au, Sn, In, Pb, Ag, Bi, Zn, and Cu.

The above objects of the present invention have also been achieved by providing a method of fabricating a package including a cap wafer combined with a base wafer adapted for packaging a circuit device, said method comprising: etching a predetermined area of a lower surface of the cap wafer to form a cavity; forming at least one viahole penetrating through upper and lower surfaces of the cap wafer in the cavity; and filling a conductive material in the at least one viahole to form at least one feed-through.

The step of forming at least one viahole penetrating through the upper and lower surfaces of the cap wafer in the cavity may include: disposing a metal layer on the lower surface, preferably on the entire lower surface of the cap wafer, in which the cavity is formed; and etching a predetermined area of an upper surface of the cap wafer to form a viahole connecting the upper surface of the cap wafer to the metal layer.

The step of forming at least one viahole penetrating through the upper and lower surfaces of the cap wafer in the cavity may include: disposing an insulating film on a side surface of the viahole.

The step of filling a conductive material in the at least one viahole to form the at least one feed-through may include: exposing the upper surface of the cap wafer to a plating solution; and plating an exposed portion of the metal layer with a conductive material through the viahole to fill the viahole with the conductive material.

The method may further include: etching the metal layer disposed on the lower surface of the carp wafer in a predetermined pattern to form a pad connected to the feed-through; and disposing a sealing layer bonding the base wafer to a circuit device on the lower surface of the cap wafer and a surface of the pad.

The above objects of the present invention have also been achieved by providing a method of fabricating a feed-through penetrating through upper and lower surfaces of a cap wafer, including: disposing a metal layer on a first surface of the cap wafer; etching a second surface of the cap wafer to form at least one viahole connected to and exposing a portion of the metal layer; exposing the second surface of the cap wafer to a plating solution; and plating the viahole with a conductive material using a portion of the predetermined metal layer exposed through the viahole as a seed layer to thereby fill the viahole.

Preferably, the metal layer is deposited on the entire first surface of the cap wafer.

### BRIEF DESCRIPTION OF THE DRAWINGS

The above aspects and features of the present invention will be more apparent by describing certain embodiments of the present invention with reference to the accompanying drawings, in which:

FIG. 1 is a vertical cross-sectional view of a conventional semiconductor package including a cap wafer;

FIG. 2 is a vertical cross-sectional view of another conventional semiconductor package including a cap wafer;

FIG. 3 is a vertical cross-sectional view of a cap wafer according to an embodiment of the present invention and a packaged semiconductor device fabricated using the cap wafer;

FIG. 4 is a horizontal cross-sectional view of the cap wafer shown in FIG. 3;

FIGS. 5A through 5E are vertical cross-sectional views illustrating a method of fabricating the cap wafer shown in FIG. 3;

FIG. 6 is a vertical cross-sectional view of a cap wafer according to another aspect of the present invention;

FIGS. 7A through 7E are vertical cross-sectional views illustrating a method of fabricating the cap wafer shown in FIG. 6;

FIG. 8 is a vertical cross-sectional view of a cap wafer according to yet another aspect of the present invention; and

FIGS. 9A through 9G are vertical cross-sectional views illustrating a method of fabricating the cap wafer shown in FIG. 8.

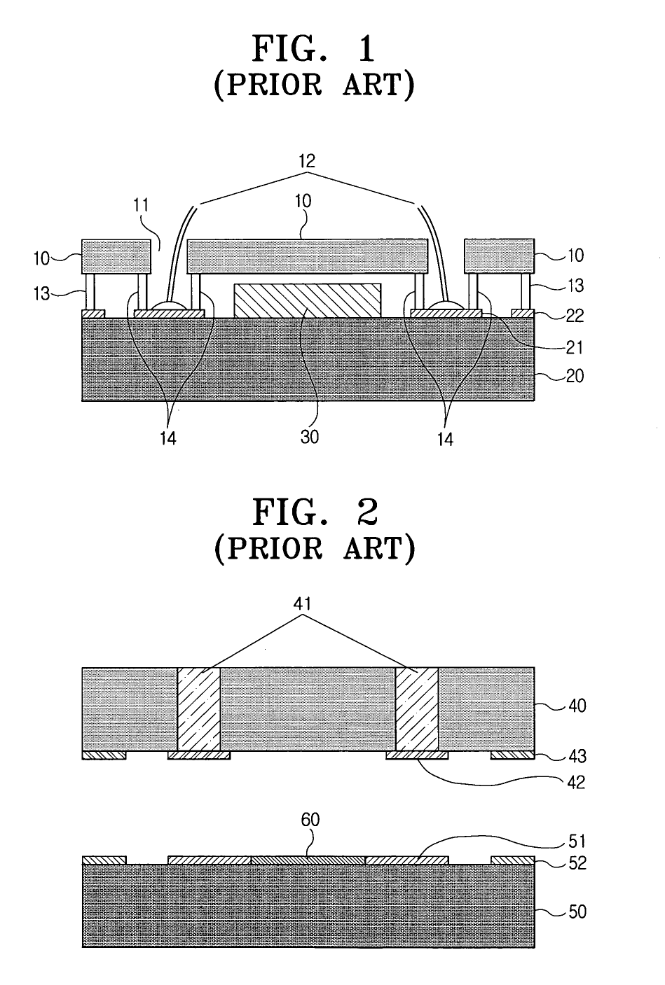

### DETAILED DESCRIPTION OF THE PREFERRED EMBODIMENTS

Certain embodiments of the present invention will be described in greater detail with reference to the accompanying drawings.

In the following description, the same drawing reference numerals are used for the same elements shown in different drawings. The following detailed description as to construction and structural elements are provided to assist in a comprehensive understanding of the invention. However, the present invention should not be construed as being limited thereto. Also, well-known functions or constructions are not described in detail since they would obscure the invention in unnecessary detail.

FIG. 3 is a vertical cross-sectional view of a cap wafer according to an embodiment of the present invention and a packaged semiconductor device fabricated using the cap wafer. Referring to FIG. 3, a cap wafer 100 includes a feed-through 110, a cavity 120, an upper electrode 145, a lower electrode 130a, a pad 130b, and a first sealing layer 140. As shown in FIG. 3, a base wafer 150 is combined with the cap wafer 100 to form a semiconductor device. A predetermined type of circuit device 160 is formed in the center of an upper surface of the base wafer 150, and a second sealing layer 151 is stacked at an edge of the upper surface of the base wafer 150.

As described above, the cap wafer 100 means a packaging wafer which is combined with the base wafer 150 for packaging the circuit device 160. Thus, if the cap wafer 100 is boned to the base wafer 150, a packaged circuit device 160 is formed.

The cavity 120 is used to secure a space in which the circuit device 160 formed on the upper surface of the base wafer 150 is built. Thus, the area of the cavity 120 is somewhat greater than the area of the circuit device 160, and the depth of the cavity 12 is greater than the height of the circuit device 160.

The feed-through 110 is formed in the cavity 120 so as to penetrate through upper and lower surfaces of the cap wafer 100. To form the feed-through 100, the cap wafer 100 may be etched to form a viahole, and then a conductive material is filled in the viahole using a plating process. The number of feed-throughs 110 may equal the number of leads (not shown) of the circuit device 160, and the lower electrode 130a is formed at a bottom of the feed-through 110 for electrically connecting to the leads of the circuit device 160. The upper electrode 145 is formed at the top of the feed-through 110 electrically connecting to an external electrode.

The pad 130b and the first sealing layer 140 are disposed on a portion of the lower surface of the cap wafer 100 except the cavity 120. The pad 130b may serve to electrically connect another circuit device formed on the base wafer 150 to the circuit device 160. Alternatively, the pad 130b may serve as a gasket sealing the circuit device 160 when the cap wafer 100 is bonded to the base wafer 150.

The first sealing layer 140 disposed on the pad 130b and the lower electrode 130a reacts with the second sealing layer 151 disposed on the base wafer 150 so as to bond the cap wafer 100 to the base wafer 150. In this case, the first and second sealing layers 140 and 151 may be formed of Au, Sn, In, Pb, Ag, Bi, Zn or Cu. Alternatively, the first and second sealing layers 140 and 151 may be formed of a combination of at least two or more of Au, Sn, In, Pb, Ag, Bi, Zn and Cu. Thus, if appropriate temperature and pressure are applied, the first and second sealing layers 140 and 151 react and thus are combined with each other so as to form a package. As a result, the packaged semiconductor is completed. In the packaged semiconductor, the circuit device 160 is positioned in the cavity 120 and electrically connected to the feedthrough 110 via the lower electrode 130a.

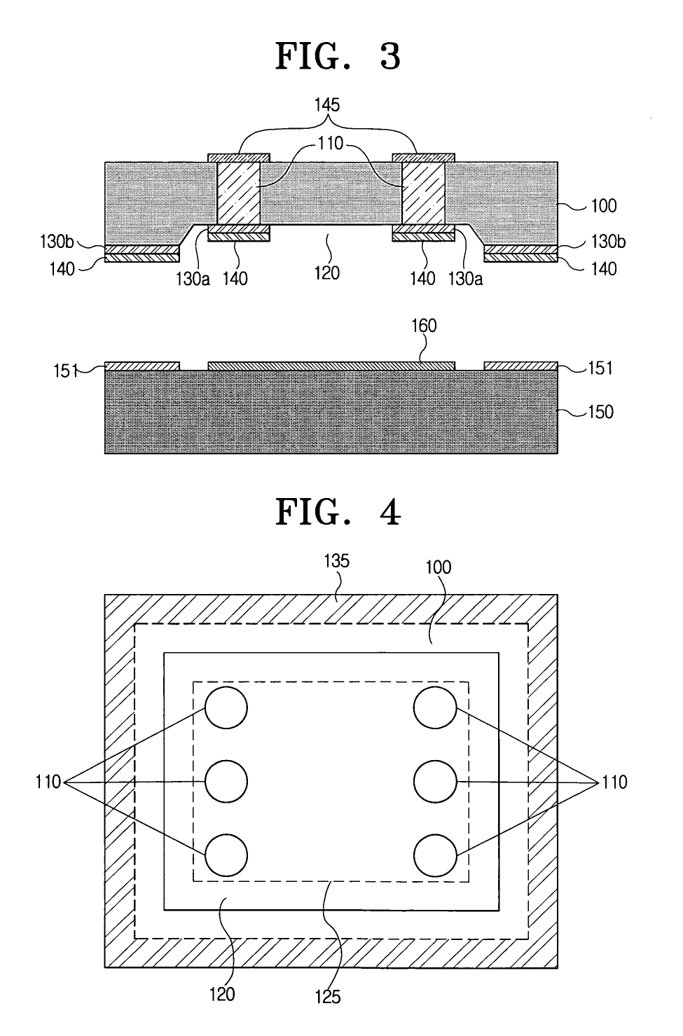

FIG. 4 is a horizontal cross-sectional view of the cap wafer 100 shown in FIG. 3. Referring to FIG. 4, the cavity 120 having a predetermined size is formed in the lower surface of the cap wafer 100. The area of the cavity 120 is greater than the area of a region 125 in which a circuit device is to be mounted. As shown in FIG. 4, a plurality of feed-throughs 110 are formed in an area of the lower surface of the cap wafer 100 in which the cavity 120 is positioned. An edge of the lower surface of the cap wafer 100 is a bonding area 135 bonded to the base wafer 150 using the sealing layer 140.

If the feed-throughs 110 are formed in the cavity 120 as in the present embodiment, the feed-throughs 110 may be directly connected to the leads of the circuit device 160. Thus, an additional connector (not shown) does not need to be formed on the surface of the base wafer 150. As a result, the whole area (foot print) of the semiconductor package can be reduced. Also, positions of the feed-throughs 110 are spaced apart from a portion bonded to the base wafer 150. Thus, although high temperature and pressure are applied to the feed-throughs 110 during bonding, the resulting expansion or deformation does not affect bonding. Consequently, the packaged device yield is improved.

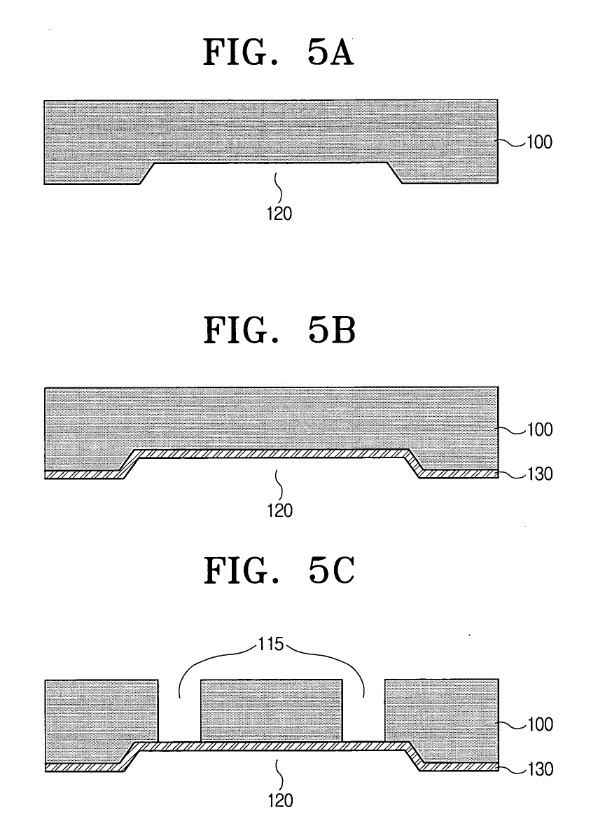

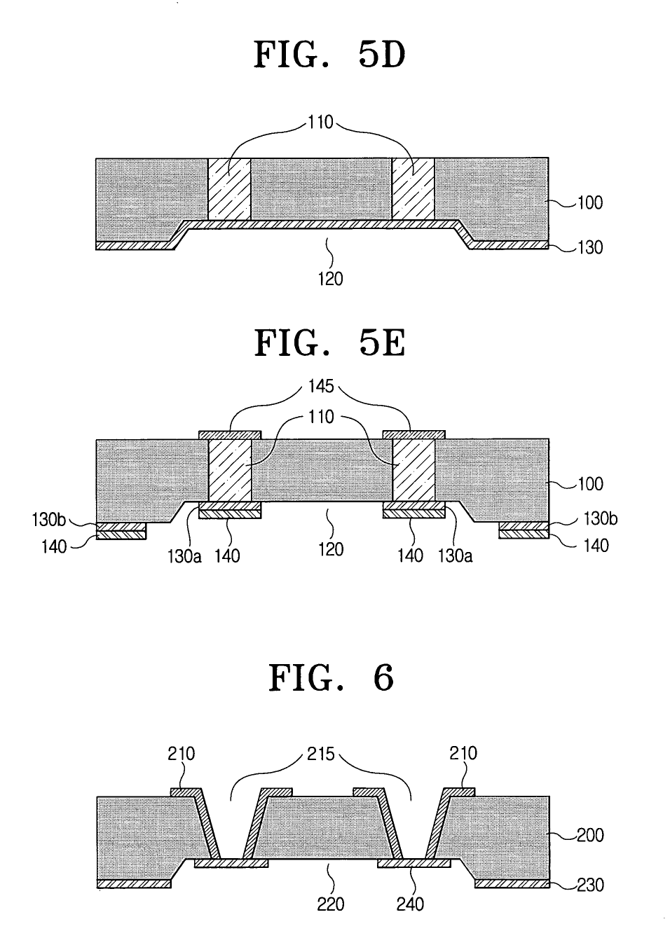

FIGS. 5A through 5E are vertical cross-sectional views illustrating a method of fabricating the cap wafer 100 shown in FIG. 3. Referring to FIG. 5A, a predetermined area of the lower surface of the cap wafer 100 is etched to form the cavity 120. The area and the depth of the cavity 120 are determined depending on a size of a circuit device to be housed therein.

As shown in FIG. 5B, a metal layer 130 is disposed on the entire lower surface of the cap wafer 100. The metal layer 130 serves as a seed layer in a plating process that will be described below.

As shown in FIG. 5C, an upper surface of the cap wafer 100 is etched to form at least one or more viaholes 115. In this case, an area of the cap wafer 100 in which the cavity 12 is formed is etched so as to expose a portion of the metal layer 130.

As shown in FIG. 5D, the upper surface of the cap wafer 100 is exposed to a plating solution to plate the exposed portion of the metal layer 130 with a conductive material so as to fill the viaholes 115.

As shown in FIG. 5E, the metal layer 130 disposed on the lower surface of the cap wafer 100 is etched in a predetermined pattern to form the lower electrode 130a and the pad 130b. A predetermined conductive material is disposed and patterned on the upper surface of the cap wafer 100 to form the upper electrode 145. Also, the first sealing layer 140 is formed on the lower electrode 130a and the pad 130b. In this case, the first sealing layer 140 and the upper electrode 145 may be formed at the same time by disposing and patterning a predetermined conductive material on the upper and lower surfaces of the cap wafer 100.

To fabricate the packaged semiconductor shown in FIG. 3, the base wafer 160, which includes the upper surface on which the circuit device 160 and the second sealing layer 151 are formed, is additionally fabricated and then bonded to the cap wafer 100.

In this case, a direct bonding method of heating to a predetermined temperature, an anodic bonding method of applying a voltage, a bonding method using an adhesive such as an epoxy or the like, or a eutectic bonding method using a metal may be employed. However, the direct bonding method and the anodic bonding method require a relatively high temperature. Thus, alternatively, the bonding method which uses an adhesive or the eutectic bonding method may be used.

Referring to FIGS. 5B through 5D, a plating method using only the metal layer 130 as a seed layer is disclosed. In other words, the metal layer 130 is fully disposed on a surface of the cap wafer 100, and then the other surface of the cap wafer 100 is etched to form the viaholes 115 connected to the metal layer 130 as shown in FIG. 5C. Thus, if the other surface of the cap wafer 100 is exposed to the plating solution, the exposed portion of the metal layer 130 at the bottoms of the viaholes 115 serves as a seed, and thus plating is performed along the viaholes 115 as shown in FIG. 5D. As a result, if the viaholes 115 are filled, the viaholes 115 may be used as feed-throughs. The above-described plating method can contribute to preventing the generation of cracks or voids in the viaholes 115

FIG. 6 is a vertical cross-sectional view of a cap wafer according to another aspect of the present invention. Referring to FIG. 6, cap wafer 200 includes a metal layer 210, a viahole 215, a cavity 220, a sealing layer 230, and a pad 240.

As in the previous embodiment described with reference to FIG. 3, the cavity 220 is a portion in which a circuit device (not shown) is housed in a packaging process and is formed in a predetermined area of a lower surface of the cap wafer 200. At least one viahole 215 is formed in the cavity 220 so as to penetrate through upper and lower surfaces of the cap wafer 220. The number of viaholes 215 may be determined depending on a number of leads of the circuit device. The metal layer 210 is disposed on a side surface of the viahole 215. The metal layer 210 serves as an electrode instead of the feed-through 110 described in the previous embodiment shown in FIG. 3. In other words, instead of forming the feed-through 110 using a plating method, a thin layer is formed of a conductive material so as to serve as both the feed-through 110 and upper electrode 145.

The pad 240 is disposed on an area of the lower surface of the cap wafer 200 in the cavity 220 to electrically connect the metal layer 210 to the circuit device. Also, the sealing layer 230 is formed in an area of the lower surface of the cap wafer 200 except the cavity 220 so as to be bonded to a base wafer (not shown).

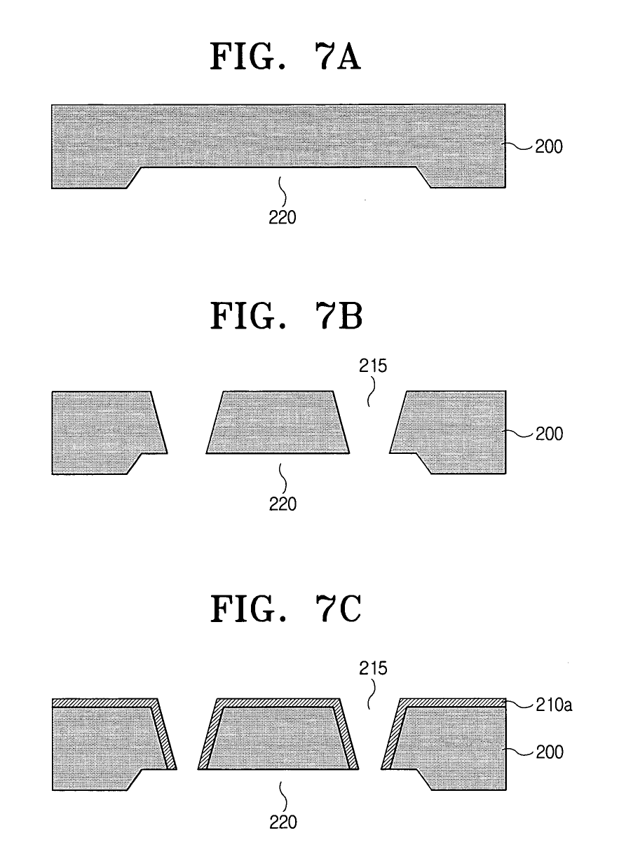

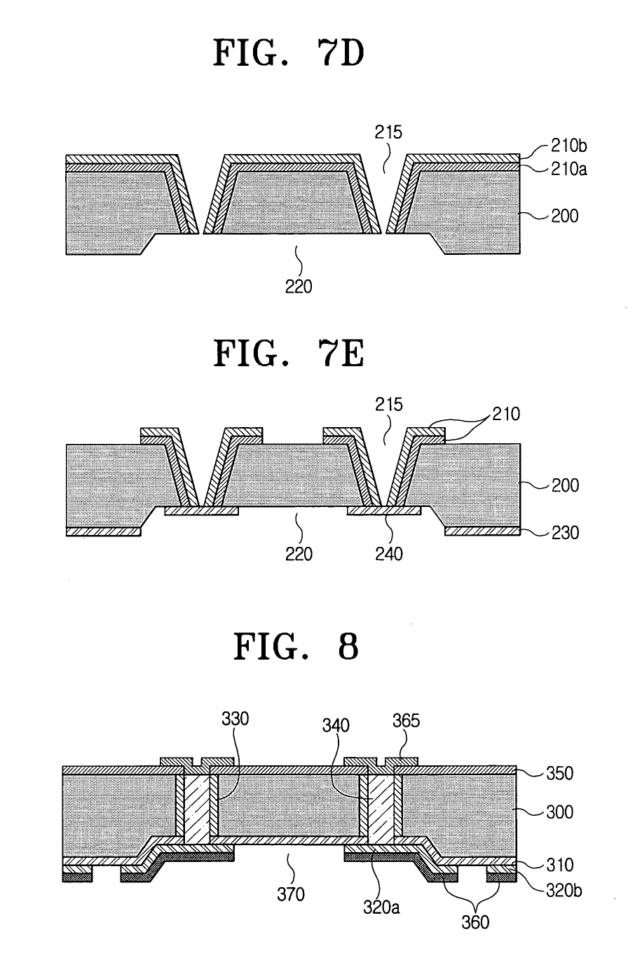

FIGS. 7A through 7E are vertical cross-sectional views illustrating a method of fabricating the cap wafer 200 shown in FIG. 6. The cavity 220 is formed on the cap wafer 200 as shown in FIG. 7A, and the at least one viahole 215 is formed in the cavity 220 so as to penetrate through the cap wafer 200 as shown in FIG. 7B. In this case, the side surface of the viahole 215 may be slanted to easily stack or rather deposit the metal layer 210.

Next, a seed layer 210a is disposed on the side surface of the viahole 215 and an upper surface of the cap wafer 200 as shown in FIG. 7C. Thereafter, a metal thin layer 210b is disposed along the seed layer 210a as shown in FIG. 7D.

As shown in FIG. 7E, the seed layer 210a and the metal thin layer 210b are patterned in a predetermined shape, and a conductive material is disposed on the lower surface of the cap wafer 200 to form the pad 240 and the sealing layer 230.

FIG. 8 is a vertical cross-sectional view of a cap wafer according to yet another aspect of the present invention. Referring to, FIG. 8, cap wafer 300 includes a first insulating layer 310, a lower electrode 320a, a pad 320b, an insulating film 330, a feed-through 340, a sealing layer 360, an upper electrode 365, and a cavity 370.

The function and position of the cavity 370 are as described in the previous embodiment and thus will not be repeated. The insulating film 330 and the feed-through 340 are formed in the cavity 370. The insulating film 330 insulates the feed-through 340 from the cap wafer 300. In this regard, in the case where an electric signal having a DC component is applied to a circuit device (not shown) through the feed-through 340, the electric signal may leak into the cap wafer 300 or the like. Thus, the insulating film 330 can contribute to preventing the electric signal from leaking into the cap wafer 300 or the like.

The upper electrode 365 is formed on an upper surface of the cap wafer 300 so as to be connected to the feed-through 340, and the lower electrode 320a is formed on a lower surface of the cap wafer 300. In this case, the first insulating layer 310 is formed on the lower surface of the cap wafer 300 so as to insulate the lower electrode 320a from the cap wafer 300, and a second insulating layer 350 is disposed on the upper surface of the cap wafer 300 to insulate the upper electrode 365 from the cap wafer 300. The lower electrode 320a is disposed on an inner portion of the cavity 370, a portion outside the cavity 370, and a surface of the first insulating layer 310. A portion of the lower electrode 320 in the cavity 370 is electrically connected to the circuit device as described above. A portion of the lower electrode 320a disposed on the portion outside the cavity 370 may serve as a gasket together with the sealing layer 360 so as to seal the circuit device.

The lower electrode 320a and the pad 320b may be formed at the same time by patterning the metal layer 320 used as a seed layer in a plating process of forming the feed-through 330. The sealing layer 360 is disposed on surfaces of the lower electrode 320a and the pad 320b so as to be bonded to a base wafer (not shown).

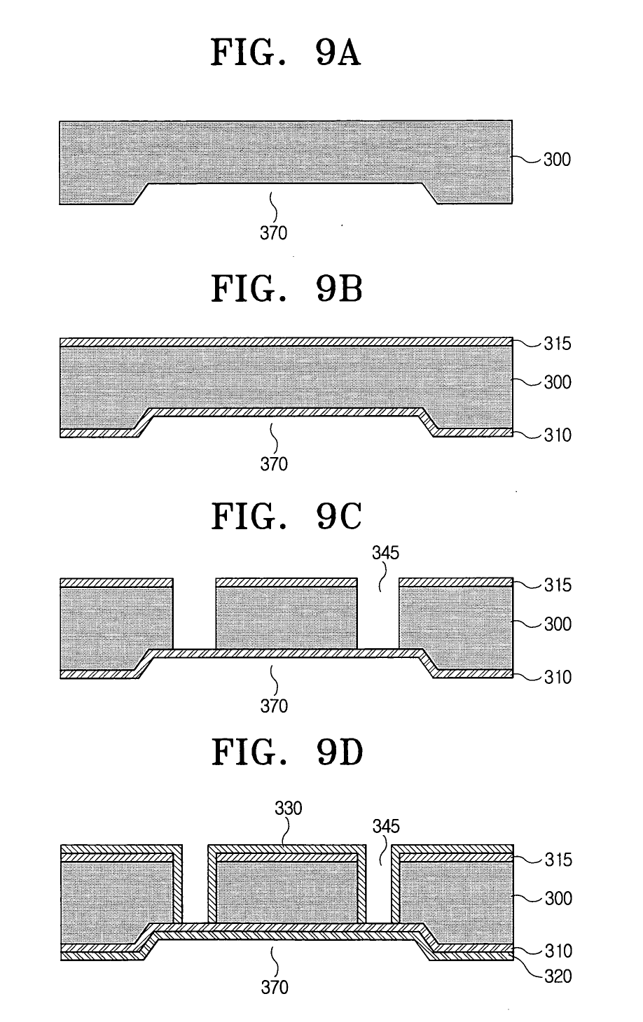

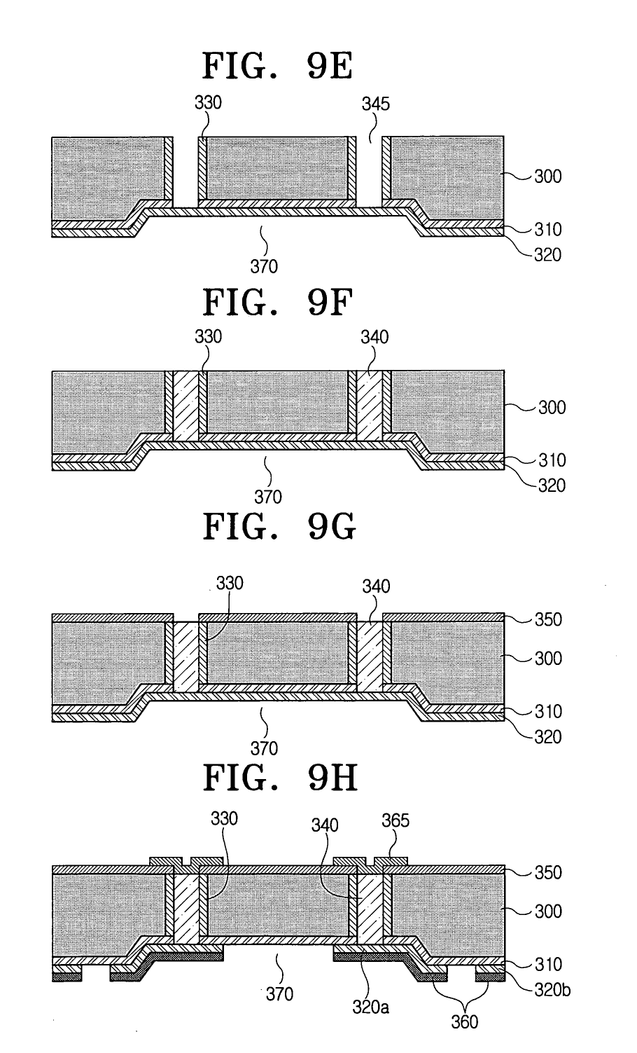

FIGS. 9A through 9G are vertical cross-sectional views illustrating a method of fabricating the cap wafer 300 shown in FIG. 8. As shown in FIG. 9A, a predetermined area of the lower surface of the cap wafer 300 is etched to form the cavity 370. Next, as shown in FIG. 9B, first insulating layers 310 and 315 are formed on the upper and lower surfaces of the cap wafer 300.

As shown in FIG. 9C, a predetermined area of the first insulating layer 315 on the upper surface of the cap wafer 300 is etched to expose the cap wafer 300. Next, the exposed portion of the cap wafer 300 is etched to form a viahole 345. As shown in FIG. 9D, the insulating film 330 is formed on the entire upper surface of the cap wafer 300, and then the metal layer 320 is disposed on the surface of the first insulating layer 310 on the lower surface of the cap wafer 300. Thus, the insulating film 330 is disposed on an inner surface of the viahole 345 and the first insulating layer 315.

As shown in FIG. 9E, a portion of the insulating film 330 disposed on the bottom of the viahole 345 is etched to expose the metal layer 320.

As shown in FIG. 9F, a portion of the metal layer 320 exposed in the viahole 345 is used as a seed layer to perform plating. Thus, a conductive material is filled in the viahole 345 to form the feed-through 340.

As shown in FIG. 9G, the second insulating layer 350 is disposed on the upper surface of the cap wafer 300.

As shown in FIG. 9H, a conductive material is disposed and patterned above and below the cap wafer 300 to form the upper electrode 365, the lower electrode 320a, and the pad 320b. The sealing layer 360 is disposed on the lower electrode 320a and the pad 320b. As described above, the sealing layer 360 may be formed of Au, Sn, In, Pb, Ag, Bi, Zn, Cu, or a combination of at least two of Au, Sn, In, Pb, Ag, Bi, Zn and Cu. Thus, the sealing layer 360 may be formed of a low temperature fusion material such as AuSn, InSn, or the like so as to allow for bonding at a low temperature.

The cap wafers 100, 200, and 300 of the above-described embodiments may be general silicon wafers, high resistivity silicon wafers, glass wafers, or the like.

As described above, the present invention provides a cap wafer including a cavity, a packaged semiconductor including the cap wafer, and a method of fabricating the cap wafer. A circuit device can be mounted in the cavity. Also, a viahole is formed in the cavity so as to connect the circuit device to an external electrode via the viahole. Thus, the area of a pad connected to the circuit device can be reduced. As a result, the entire size (footprint) of the semiconductor package can be reduced. In addition, the bonding area is different from the viahole positions. Thus, although an electrode in the viahole is thermally-expanded or thermally shrunk and thus deformed due to high temperature and high pressure applied during bonding, the thermal expansion or the thermal shrinkage does not affect bonding. In other words, the yield of fabricating the packaged semiconductor can be improved. According to an aspect of the present invention, an insulating layer can be further included between an electrode and the cap wafer so as to prevent leakage of an electric signal having a DC component. Also, a seed layer can be disposed below the viahole and plated in a process of fabricating a feed-through so as to prevent cracks or voids from being generated in the viahole

The foregoing embodiment and advantages are merely exemplary and are not to be construed as limiting the present invention. The present teachings can be readily applied to other types of apparatuses. Also, the description of the embodiments of the present invention is intended to be illustrative, and not to limit the scope of the claims, and many alternatives, modifications, and variations will be apparent to those skilled in the art.

What is claimed is:

1. A cap wafer adapted for packaging a current device in combination with a base wafer, said cap wafer comprising:
a cavity formed in a predetermined area of a lower surface of the cap wafer;
and at least one feed-through penetrating through upper and lower surfaces of the cap wafer and connecting to the cavity.

2. The cap wafer of claim 1, further comprising:
an insulating film formed between the feed-through and the cap wafer, said insulating film insulating the feed-through from the cap wafer.

3. The cap wafer of claim 1, further comprising:
a pad formed on the lower surface of the cap wafer, said pad being connected to the feedthrough.

4. The cap wafer of claim 3, further comprising:
a sealing layer disposed on an area of the lower surface of the cap wafer except the cavity.

5. The cap wafer of claim 4, wherein the sealing layer comprises at least one selected from the group consisting of Au, Sn, In, Pb, Ag, Bi, Zn and Cu.

6. A packaged semiconductor comprising;
a base wafer comprising an upper surface having a predetermined area in which a circuit device is formed;
a cap wafer having a cavity formed in a predetermined area of a lower surface of the cap wafer, the cap wafer being combined with the base wafer so as to position the circuit device in the cavity and package the same; and
at least one feed-through penetrating through upper and lower portions of the cap wafer, connecting to the cavity and electrically connecting to the circuit device.

7. The packaged semiconductor of claim 6, further comprising:
an insulating film formed between the feed-through and the cap wafer, said insulating film insulating the feed-through from the cap wafer.

8. The packaged semiconductor of claim 6, further comprising:
a pad electrically connecting the feed-through to the circuit device.

9. The packaged semiconductor of claim 6, further comprising:
a first sealing layer disposed on an area of the lower surface of the cap wafer except the cavity; and
a second sealing layer disposed on a portion of the upper surface of the base wafer at a position corresponding to the first sealing layer, said cap wafer bonding to the base wafer by reaction of the first and second sealing layers.

10. The packaged semiconductor of claim 9, wherein at least one of the first and second sealing layers comprises at least one selected from the group consisting of Au, Sn, In, Pb, Ag, Bi, Zn and Cu.

11. A package including a cap wafer combined with a base wafer adapted for packaging a semiconductor device, said package comprising:
a cavity formed in a predetermined area of a lower surface of the cap wafer;
at least one viahole positioned in the cavity and penetrating through upper and lower surfaces of the cap wafer; and
a metal layer disposed on a side surface of the viahole.

12. The package of claim 11, further comprising:
an insulating film formed between the metal layer and the cap wafer, said insulating film insulating the metal layer from the cap wafer.

13. The package of claim 11, further comprising:
a pad formed in the cavity on the lower surface of the cap wafer for connecting to the metal layer.

14. The package of claim 13, further comprising:
a sealing layer disposed on a predetermined area of the lower surface of the cap wafer except the cavity.

15. The package of claim 14, wherein the sealing layer comprises at least one selected from the group consisting of Au, Sn, In, Pb, Ag, Bi, Zn and Cu.

16. A method of fabricating a package including a cap wafer combined with a base wafer adapted for packaging a circuit device, said method comprising:
etching a predetermined area of a lower surface of the cap wafer to form a cavity;
forming at least one viahole penetrating through upper and lower surfaces of the cap wafer in the cavity; and
filling a conductive material in the at least one viahole to form at least one feed-through.

17. The method of claim 16, wherein said step of forming the at least one viahole comprises:
disposing a metal layer on the lower surface of the cap wafer in which the cavity is formed; and etching a predetermined area of an upper surface of the cap wafer to form a viahole connecting the upper surface of the cap wafer to the metal layer.

18. The method of claim 17, wherein said step of forming the at least one viahole comprises:
disposing an insulating film on a side surface of the viahole.

19. The method of claim 17, wherein said step of filling a conductive material in the at least one viahole comprises:
exposing the upper surface of the cap wafer to a plating solution; and
plating an exposed portion of the metal layer with a conductive material through the viahole to fill the viahole with the conductive material.

20. The method of claim 17, further comprising:
etching the metal layer disposed on the lower surface of the cap wafer in a predetermined pattern to form a pad connected to the feed-through; and
depositing a sealing layer bonding the base wafer to a circuit device on the lower surface of the cap wafer and a surface of the pad.

21. A method of fabricating a feed-through penetrating through upper and lower surfaces of a cap wafer, comprising:
depositing a metal layer on a first surface of the cap wafer;
etching a second surface of the cap wafer to form at least one viahole connected to and exposing a portion of the metal layer;
exposing the second surface of the cap wafer to a plating solution; and
plating the viahole with a conductive material using a portion of the metal layer exposed through the viahole as a seed layer to thereby fill the viahole.
